(19) United States
(12) Patent Application Publication
(10) Pub. No.: US 2009/0183762 A1
(43) Pub. Date: Jul. 23, 2009

(54) LOW-VOLTAGE TRACKING SOLAR CONCENTRATOR

(75) Inventors: Derek Jackson, Pasadena, CA (US); Gregg Bone, Santa Monica, CA (US)

Correspondence Address: KNOBBE MARTENS OLSON & BEAR LLP, 2040 MAIN STREET, FOURTEENTH FLOOR, IRVINE, CA, 92614, US

(73) Assignee: Energy Innovations Inc., Pasadena, CA (US)

(21) Appl. No.: 12/355,643

(22) Filed: Jan. 16, 2009

Related U.S. Application Data
(60) Provisional application No. 61/011,664, filed on Jan. 18, 2008.

(51) Int. Cl. H01L 31/052

(52) U.S. Cl. 136/246

(57) ABSTRACT

A solar concentrator can include at least one optical element for concentrating incident light, a receiver assembly comprising a base plate comprising a first conductive layer and second conductive layer, wherein the first conductive layer and second conductive layer are characterized by a voltage differential when exposed to light, and a plurality of photovoltaic cells mounted to the base plate, each cell comprising a first terminal connected to the first conductive layer and a second terminal connected to the second conductive layer, a frame; step-up voltage means, electrically connected to the receiver assembly, for increasing said voltage differential, an electrical circuit for conducting current generated by the receiver assembly, the circuit comprising a first conductive member configured to conduct electricity between the first conductive layer and step-up voltage means and a second conductive member configured to conduct electricity between the second conductive layer and step-up voltage means.

### CROSS-REFERENCE TO RELATED APPLICATIONS

This application claims the benefit of U.S. Provisional Application No. 61/011,664 filed on Jan. 18, 2008, titled “LOW-VOLTAGE TRACKING SOLAR CONCENTRATOR WITH INVERTER,” which is hereby expressly incorporated by reference in its entirety.

### BACKGROUND OF THE INVENTION

1. Field of the Invention

The present invention relates generally to solar concentrators.

2. Description of the Related Art

Solar concentrators can collect sunlight and direct the sunlight onto a photovoltaic cell. At least a portion of the electromagnetic energy from the sunlight can be converted by the photovoltaic cell into electrical power. The photovoltaic cell includes a photovoltaic active material, for example, crystalline silicon or gallium-arsenide. A concentrator may be used to increase the power output from a photovoltaic cell. Because some photovoltaic active materials may produce more power at higher sunlight levels than at ordinary sunlight levels, a concentrator may cause a photovoltaic cell to produce more power than a photovoltaic cell that is not coupled with a concentrator.

### SUMMARY OF THE INVENTION

Certain embodiments of the invention include solar concentrators configured to convert electromagnetic waves incident upon the concentrators to electrical power. This may minimize the amount of photovoltaic active material required to produce a desired amount of electrical power and limit the footprint required to produce the power.

A solar concentrator comprising at least one optical element for concentrating incident light, a receiver assembly comprising a base plate comprising a first conductive layer and second conductive layer, wherein the first conductive layer and second conductive layer are characterized by a voltage differential when exposed to light, and a plurality of photovoltaic cells mounted to the base plate, each cell comprising a first terminal connected to the first conductive layer and a second terminal connected to the second conductive layer, a frame for supporting the at least one optical element and receiver assembly, step-up voltage means, electrically connected to the receiver assembly, for increasing said voltage differential, an electrical circuit for conducting current generated by the receiver assembly, the circuit comprising a first conductive member configured to conduct electricity between the first conductive layer and step-up voltage means, and a second conductive member for configured to conduct electricity between the second conductive layer and step-up voltage means. The first conductive member can be configured to conduct a current of non-zero voltage, and the first conductive member consists essentially of a first portion of said frame. The second conductive member can be configured to provide a ground connection, and wherein the second conductive member consists essentially of a second portion of said frame different than the first portion.

Additionally, the first conductive layer can be substantially planar and configured to connect directly to the first portion of said frame, and the second conductive layer can be substantially planar and configured to connect directly to the second portion of said frame, and the first portion and second portion are electrically isolated from each other. The first conductive layer and second conductive layer can be substantially parallel, and the first conductive layer can extend beyond the second conductive layer to form a first offset, and the second conductive layer can extend beyond the first conductive layer to form a second offset. In such embodiments, the first conductive layer can be configured to connect to the first portion of said frame at the first offset, and the second conductive layer can be configured to connect to the second portion of said frame at the second offset. The first offset of the first conductive layer of the base plate can be further configured to connect to an offset of a second base plate, whereby the base plate can be electrically connected in series or parallel with the second base plate. The first conductive member can be configured to conduct a current of non-zero voltage, a portion of the first conductive member consists essentially of a first rail mounted to said frame, and the second conductive member consists essentially of a second rail mounted to said frame. In some embodiments the first conductive layer is substantially planar and configured to connect directly to the first rail, the second conductive layer is substantially planar and configured to connect directly to the second rail, and the first rail and second rail are electrically isolated from each other. The step-up voltage means can comprise one or more circuit components, for example, an inverter, a converter, or a combination thereof. The voltage differential provided to the step-up voltage means can be in the range of between about 0.5 volts and about 48 volts. Also, the voltage differential provided to the step-up voltage means can be between 2 volts and 4 volts.

One embodiment includes a solar concentrator device includes a base plate comprising a planar first conductive layer, a planar second conductive layer, and a planar insulating layer disposed between the first and second conductive layers. A plurality of alignment features can be disposed on the base plate, for aligning the support, or the secondary lens assembly to the base plate. The device can further include a primary lens, a secondary lens system disposed between the primary lens and the base plate, and a support connected to the base plate and the primary lens for holding the primary lens above the secondary lens system, where the support is connected to the base plate at the plurality of first alignment features. The primary and secondary lens systems can include one or more of comprises reflective, refractive, and diffractive optics, and in particular a Fresnel lens. The device can further comprise a photovoltaic cell, disposed below the secondary lens system to receive concentrated light propagating through the secondary lens system. The photovoltaic cell is electrically connected to the first and second conductive layers. For example, the photovoltaic cell is electrically connected to the first conductive layer via interconnects, and connected to the second conductive layer by a die attachment material. The photovoltaic cell can be embedded within the base plate, in a hole aperture or socket. A heat sink can be thermally connected to the base plate. the base plate can include a thermally conductive material for dissipating heat. The photovoltaic cell can include a first terminal and a second terminal, the first terminal being electrically connected to one of the first conductive layer and the second conductive layer and the second terminal being electrically connected to the other of the first conductive layer and the second conductive layers.

In another embodiment, a method of manufacturing a solar concentrator module, comprises providing a planar base plate comprising a first conductive layer, a second conductive layer, an insulator layer disposed between the first and second conductive layers, a plurality of first alignment features, and a plurality of apertures formed in the first conductive layer and insulator layer that expose the second conductive layer for holding a photovoltaic device, disposing a photovoltaic cell in each of the plurality of apertures such that the photovoltaic cell is electrically connected to the first and second conductive layers to provide power to the first and second conductive layers, connecting a secondary lens system to the base plate over each photovoltaic cell, connecting a first end of a support to the base plate at the location of the plurality of first alignment features, and connecting a planar primary lens to a second end of the support. The method can further comprise connecting one or more heat sinks to the base plate proximal to the second conductive layer. In one aspect, connecting a primary lens to the second end of the support comprises heating a polymer layer of the primary lens at one or more locations, and pressing the second end of the support into the polymer layer at the heated locations. The primary lens can be bonded to the second end of the support with an adhesive. The primary lens can also be connected to the second end of the support by fitting the second end of the support within secondary alignment features formed on the primary lens.

In another embodiment a solar concentrator module includes a base plate including a planar first conductive layer, a planar second conductive layer, and a planar insulating layer disposed between the first and second conductive layers, a planar primary lens, at least two solar concentrator devices disposed on the base plate, each device comprising a secondary lens system disposed on the base plate, and a photovoltaic cell disposed below the secondary lens system and aligned to receive light propagating through the secondary lens system, the photovoltaic cell electrically connected to the first and second conductive layers, a support connected to the base plate and the primary lens for holding the primary lens above the secondary lens systems, and a plurality of first alignment features disposed on the base plate for aligning the support to the base plate, where the support is connected to the base plate at the plurality of first alignment features.

Another embodiment includes a solar concentrator module, comprising a base plate having a planar first conductive layer, a planar second conductive layer, and a planar insulating layer disposed between the first and second conductive layers, and at least two solar concentrator devices disposed on the base plate.

An embodiment includes a solar concentrator module comprising a base plate comprising a planar first conductive layer; and a planar second conductive layer disposed substantially parallel to the first conductive layer and at least a portion of the second conductive layer offset from the first conductive layer such that an edge portion of the second conductive layer is not vertically coincident along a vertical line normal to the planar direction of the second conductive layer. The first conductive layer can be offset from the second conductive layer on a first side and a second side of the base plate.

In another embodiment a solar concentrator module comprises a base plate having a planar first conductive layer, a planar second conductive layer, and a planar insulating layer disposed between the first and second conductive layers, and a plurality of solar concentrator units disposed on the base plate, each solar concentrator unit comprising a photovoltaic cell electrically connected to the first conductive layer and second conductive layer.

Another embodiment includes a solar concentrating system comprising a plurality of solar concentrating modules, each solar concentrating module comprising a base plate comprising a planar first conductive layer and a planar second conductive layer disposed substantially parallel to the first conductive layer and at least a portion of the second conductive layer offset from the first conductive layer such that an edge portion of the second conductive layer is not vertically coincident along a vertical line normal to the planar direction of the second conductive layer, where one of the first conductive layer and second conductive layer of each of the solar concentrating modules is electrically connected to one of the first conductive layer and second conductive layer of at least one other solar concentrating module such that the plurality of solar concentrating modules are electrically connected in series.

Another embodiment includes a solar concentrating system comprising a plurality of solar concentrating modules, each solar concentrating module comprising a base plate having a planar first conductive layer, a planar second conductive layer disposed substantially parallel to the first conductive layer, and an insulating layer disposed between the first conductive layer and second conductive layer, where one of the first conductive layer and second conductive layer of each of the solar concentrating modules is electrically connected to one of the first conductive layer and second conductive layer of at least one other solar concentrating module such that the plurality of solar concentrating modules are connected in series.

Another embodiment includes a solar concentrating system comprising a plurality of solar concentrating modules, each solar concentrating module comprising a base plate having a first conductive layer, a planar second conductive layer disposed substantially parallel to the first conductive layer, and an insulating layer disposed between the first conductive layer and second conductive layer, where one of the first conductive layer and second conductive layer of each of the solar concentrating modules is electrically connected to one of the first conductive layer and second conductive layer of at least one other solar concentrating module such that the plurality of solar concentrating modules are connected in parallel.

Another embodiment includes a solar concentrating system comprising at least one solar concentrating module, each solar concentrating module comprising a base plate having a planar first conductive layer, a planar second conductive layer disposed parallel to the first conductive layer, and an insulating layer disposed between the first conductive layer and second conductive layer, and a plurality of photovoltaic cells configured to produce electricity when exposed to sunlight, the plurality of photovoltaic cells being electrically connected to the first conductive layer and second conductive layer, and a frame configured to support the at least one solar concentrating module.

### BRIEF DESCRIPTION OF THE DRAWINGS

Example embodiments disclosed herein are illustrated in the accompanying schematic drawings, which are for illustrative purposes only. The drawings are not drawn to scale, unless otherwise stated as such, or necessarily reflect relative sizes of illustrative aspects of the embodiments.

FIG. 1 is a cross-section view schematically illustrating a solar concentrating unit.

FIG. 2 is a cut-away view schematically illustrating a module of solar concentrating units.

FIG. 3A is a perspective view schematically illustrating a group of solar concentrating modules.

FIG. 3B is a perspective view schematically illustrating a group of solar concentrating modules electrically connected to an inverter or converter.

FIG. 4 is a perspective view schematically illustrating a frame with a conductive bus that can structurally support solar concentrating modules and conduct power.

FIG. 4A is a cross-section view schematically illustrating the frame of FIG. 4 taken along line 4A-4A.

FIG. 4B is a close-up view of a section of FIG. 4.

FIG. 5 is a cross-section view schematically illustrating a frame with a conductive bus.

FIG. 6A is a perspective view schematically illustrating an offset base sheet.

FIG. 6B is a perspective view schematically illustrating an offset base sheet.

FIG. 7 is a side view schematically illustrating a series connection between two offset base sheets.

FIG. 8A is a perspective view schematically illustrating another embodiment of a frame that can structurally support solar concentrating modules and conduct power, where the frame includes conductive material and an insulating shell.

FIG. 8B is a cross-section view schematically illustrating the frame of FIG. 8 taken along line 8B-8B.

FIG. 8C is a perspective view schematically illustrating the frame shown in FIG. 8A electrically connected to an inverter or converter.

FIG. 9 is a diagram schematically illustrating a set of solar concentrating modules in a full parallel configuration.

FIG. 10 is a diagram schematically illustrating a set of solar concentrating modules in a series-parallel configuration.

FIG. 11 is a diagram schematically illustrating a set of solar concentrating modules in a full series configuration.

FIG. 12 is a diagram schematically illustrating a set of solar concentrating modules in a parallel-series configuration.

### DETAILED DESCRIPTION OF THE PREFERRED EMBODIMENT

The following detailed description is directed to certain specific embodiments of the invention. However, the invention can be embodied in a multitude of different ways. The embodiments described herein may be implemented in a wide range of devices incorporating photovoltaic cells that convert electromagnetic energy into electrical power.

In this description, reference is made to the drawings wherein like parts are designated with like numerals throughout. As will be apparent from the following description, the embodiments may be implemented in a variety of devices that comprise photovoltaic cells.

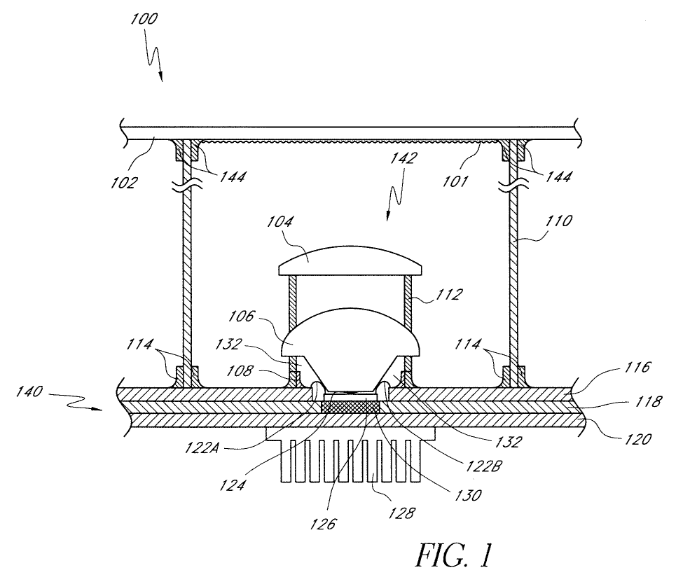

FIG. 1 is a schematic illustrating a cross-section of one embodiment of a solar concentrating unit (or device) 100. The unit 100 may be combined with a plurality of other units to form a solar light concentrating module, as indicated in FIG. 1. In one example, a module can include, 28 units arranged in a 7×4 unit matrix. It is appreciated that many other embodiment, having a different number of units arranged in a different matrix are also possible. Modules can be mounted to a one or two dimensional tracking system (not shown) that aims the units so as to collect sunlight over the course of a day. Two or more modules each comprising a plurality of units can be electrically connected (e.g., in parallel) and attached to a tracking system to form a low-voltage tracking solar concentrator.

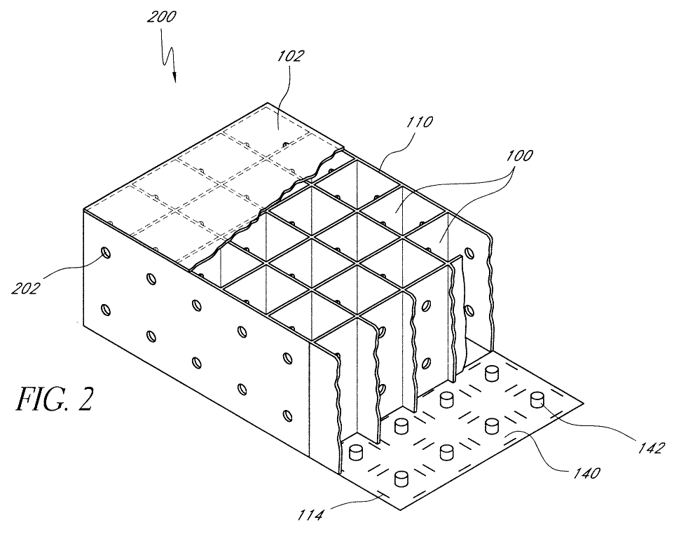

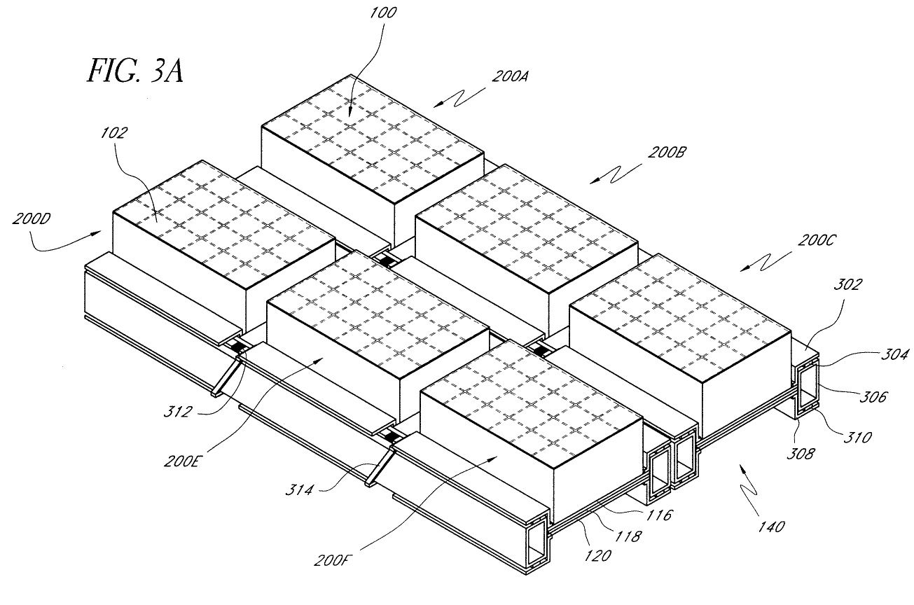

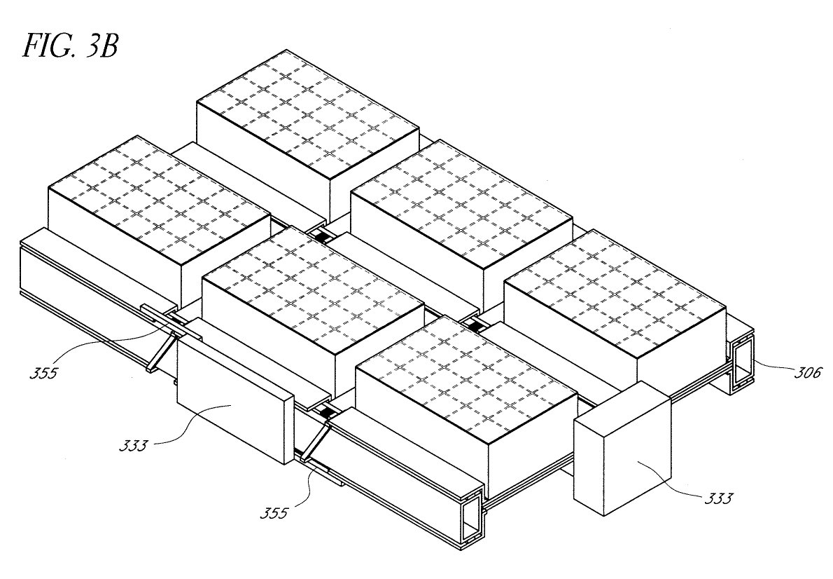

The unit 100 includes a primary lens assembly 102. The primary lens assembly 102 can be planar and operably disposed between a light source (e.g., the sun) and the rest of the components of the unit 100. The primary lens assembly 102 can be configured to have certain length and width dimensions to cover one or more units 100. The primary lens assembly 102 illustrated in FIG. 1 is a portion of the primary lens assembly 102 that covers unit 100 and also extends to cover other (e.g., contiguously positioned) solar concentrating units, as illustrated in FIGS. 2 and 3. In some embodiments (not shown), the primary lens can be formed to cover one unit such that each unit can is covered by a separate primary lens. In some embodiments the primary lens assembly 102 covers more than one unit but not all of the units in the module, for example, a “strip” of units (e.g., one unit by six units). Having a primary lens assembly 102 that covers more than one unit can be cheaper to manufacture and assemble. The primary lens assembly 102 also serves to seal the top portion of the unit 100, thus having a contiguous primary lens assembly 102 across a plurality of units can help to protect components disposed within each unit from adverse environmental conditions.

As shown if FIG. 1, the primary lens assembly 102 can include one or more optical elements, or lenses 101, for example one or more Fresnel lenses. In various embodiments, the primary lens assembly 102 may comprise reflective, refractive, and/or diffractive optics that are suitable to focus or concentrate light. To maximize the light provided to a photovoltaic cell, each portion of a lens 101 can be configured to concentrate light for the solar concentrating unit it covers. For example, the primary lens assembly 102 can include a circular Fresnel lens for each of the solar concentrating units it covers. The primary lens assembly 102 may comprises a composite of glass, or a similar substrate, and a polymer, with a lens 101 embossed in the polymer. In one embodiment, the primary lens assembly 102 may be manufactured by injection molding, placing a polymer formed to include a Fresnel lens onto a glass or plastic plate. In another embodiment, the primary lens assembly 102 may be formed by pouring a polymer onto glass and then embossing a Fresnel in the polymer. In another example, a thermoplastic polymer including a Fresnel lens may be combined with a substrate layer, for example, glass or polyethylene terephalate, to form a primary lens assembly 102. For example, a sheet of polymer that includes a plurality of Fresnel lenses can be connected to a glass plate to form the primary lens assembly 102.

The primary lens assembly 102 illustrated in FIG. 1 is supported by a supporting structure 110. The supporting structure 110 may be formed of any material capable of supporting the primary lens assembly 102. The supporting structure 110 may comprise a metal, for example, aluminum or steel. In another example, the supporting structure may comprise fiberglass, plastic, or cardboard. The primary lens assembly 102 may rest upon the supporting structure 110 or it may be connected to the supporting structure 110. For example, the primary lens assembly 102 may rest upon the supporting structure 110 and be aligned in place using lens aligning structures 144. Lens aligning structures 144 may include, for example, protrusions, tabs, extensions, pins, indents, grooves, or holes configured to align the primary lens assembly 102 with the supporting structure 110. The primary lens assembly 102 may also be connected to the supporting structure 110 using an adhesive (not shown). For example, the primary lens assembly 102 may comprise a thermoplastic polymer which may be heated to selectively re-melt certain portions of the polymer that contact the supporting structure 110 to create an adhesive to couple the primary lens assembly 102 with the supporting structure 110. In another embodiment, an adhesive is placed on selected portions, or all, of the contact points of one or both of the primary lens assembly 102 and the supporting structure 110 to connect them together.

Still referring to the embodiment illustrated in FIG. 1, the supporting structure 110 rests upon a base plate 140. The base plate 140 is configured to support the supporting structure 110 and comprises at least two conductive members configured to form at least two conductive paths. At least one of the conductive paths formed in the base plate is a non-zero voltage, or a non-ground conductive path. In other words, at least one of the first conductive member and the second conductive member is configured to conduct a current of non-zero voltage. In this embodiment, the base plate 140 includes a top electrical conductive layer 116 (or first conductive member), a middle electrical insulating layer 118, and a bottom electrical conductive layer 120 (or second conductive member). The base plate 140 and the insulating layer 118 and conductive layers 116, 120 can be relatively thin and planar. In some embodiments, the structural support aspects of the base plate can be provided solely by one or more of the conductive layers 116, 120 and the insulating layer 118. In one embodiment (not shown) another structural support layer could be included in the base plate 140.

The conductive layers 116, 120 can comprise a sheet of conductive material forming a relatively large cross-sectional conductor that minimizes electrical resistive losses when low voltage and high current electricity is conducted through the conductive layers 116, 120. The cross sectional area of the planar conductive layers is larger than wires that typically are employed to conduct electricity produced by photovoltaic cells. The conductive layers 116, 120 provide such a large cross-sectional area that the thickness of the layer, for electricity conducting purposes, may not provide enough rigidity to support other components (e.g., the primary lens assembly 102, the supporting structure 110). Thus, both the support strength and its conductivity are considered when selecting appropriate dimensions of the base plate 140. Some embodiments are configured to limit resistive losses to about 1% or less. For example, a 0.3 meter by 0.5 meter conductive layer 116, 120 comprising aluminum may have a thickness of about 1.5 μm and have about 1% resistive loss. In another example, a 1.5 meter by 2.0 meter conductive layer 116, 120 comprising aluminum may have a thickness of about 0.7 mm to have about 1% loss. In another example, the conductive layers 116, 120 comprise aluminum and have thicknesses of about 5 mm. Conductive layers can be thicker as well, for example, up to 10 mm, or even greater, and thus have increased rigidity, but such embodiments also may cost more to manufacture. Additionally, better conductors allow thinner sheets for the same loss. In some embodiments, 0.5 mm may be a practical limit for sheet thickness, because sheets less than 0.5 mm can lack the necessary structural properties and can increase the difficulty of manufacturing. However, these practical aspects may depend on the specific manufacturing processes and materials presently used. The thickness of the insulating layer 118 depends on the resistivity of the material. For common insulators, the resistivity is very high and thus, the material can be very thin. For example, the thickness of insulating layer 118 may be less than about 10 μm. In another example, the thickness of the insulating layer 118 may range between about 4 μm and 5 mm.

The top conductive layer 116 and bottom conductive layer 120 may comprise any conductive material, for example, metal plates including aluminum or copper. The middle insulating layer 118 may comprise any non-conductive material, for example, a dielectric material. An optional heat sink 128 may be disposed on the bottom conductive layer 120 and configured to dissipate heat from the base plate 140. In other embodiment, the base plate 140 itself comprises thermally conductive material and is configured to dissipate heat without needing a heat sink.

The supporting structure 110 can be aligned with a certain position on the base plate 140 by one or more alignment features 114. The alignment features 114 may comprise protrusions or extensions from the base plate 140, for example, tabs, or they may comprise other structure. For example, the alignment features may comprise holes, grooves, indents, or similar structure in the base plate 140 for the supporting structure 110 to fit into. In some embodiments the alignment features 114 are formed in the base plate as tabs which can be moved to form a protrusion from the base plate 140. Alignment features 114 can be placed on one or more locations in each unit 100. The alignment features 114 can be placed on one side, or both sides, of the supporting structure 110. In some embodiments, not every unit 100 in a module has alignment features 114, for example, every other unit may have alignment features, or only the units near the edge of the modules (or only those units interior to the modules) have alignment features 114. Also, units positioned in different locations in the module may utilize different alignment features to, for example, account for different structural stresses on the supporting structure 110.

Still referring to FIG. 1, the solar concentrating unit 100 further comprises a secondary lens assembly 142 disposed on the base plate 140. The secondary lens assembly 142 may be aligned in place on the base plate 140 by secondary alignment features 108. The secondary alignment features 108 may be similar to the alignment features 114 or they may be different. For example, the secondary alignment features 108 may comprise protrusions, tabs, extensions, pins, adhesives, indents, grooves, or holes. The secondary lens assembly 142 comprises at least one optical element, and as illustrated in this embodiment includes a first lens 104 and a second lens 106. The first lens 104 is disposed above the second lens 106, between the primary lens assembly 102 and the second lens 106. The first lens 104 and the second lens 106 may each comprise reflective, refractive, and/or diffractive optics. Both the first lens 104 and second lens 106 are supported by a housing 112. The housing 112 may comprise any material capable of supporting the first lens 104 and the second lens 106. For example, the housing may comprise metal, plastic, or fiber glass. According to one embodiment, the housing is circular. Any space between the second lens 106, the housing 112, and the base plate 140 may be filled with a sealant 132. The sealant 132 may comprise any material that is resistant to heat, light, and moisture.

Still referring to FIG. 1, the primary lens assembly 102 directs or focuses sunlight incident on the lens assembly 102 onto the secondary lens assembly 142. The first lens 104 and the second lens 106 concentrate light, and direct light, to a photovoltaic (“PV”) cell 126 disposed below the secondary lens assembly 142. The PV cell 126 may be positioned within the base plate 140 underneath the secondary lens assembly 142 and may receive the concentrated sunlight. The PV cell 126 may comprise a first terminal and second terminal (e.g., a positive terminal and negative terminal, also referred to herein as an anode and cathode) which provide power generated by the photovoltaic cell 126. In some embodiments, the photovoltaic cell 126 may be coupled to the second lens 106 with an optical coupler material 124. The optical coupler material 124 may comprise a material with a refractive index chosen to avoid inter layer reflections. In some embodiments, the photovoltaic cell 126 may be coupled to the second lens 106, while other embodiments may include another optical element between the second lens 106 and the photovoltaic cell 126 (not shown). The base plate 140 can include an aperture in the top conductive layer 116 and the middle insulating layer 118 to allow positioning of the photovoltaic cell 126 within the plate 140 above the bottom conductive layer 120. The photovoltaic cell 126 may be bonded to the bottom conductive layer 120 with a die-attachment material 130. The die-attachment material can be electrically and thermally conductive. For example, the die-attachment material may comprise solder or a conductive epoxy. The photovoltaic cell 126 may comprise any photovoltaic active material. For example, the photovoltaic cell 126 may comprise a triple junction photovoltaic active material.

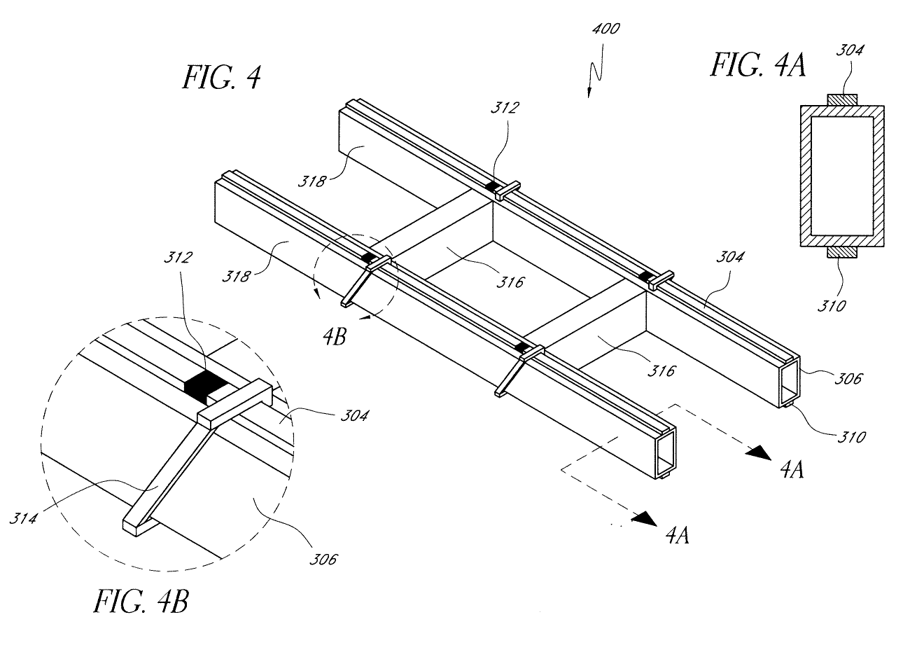

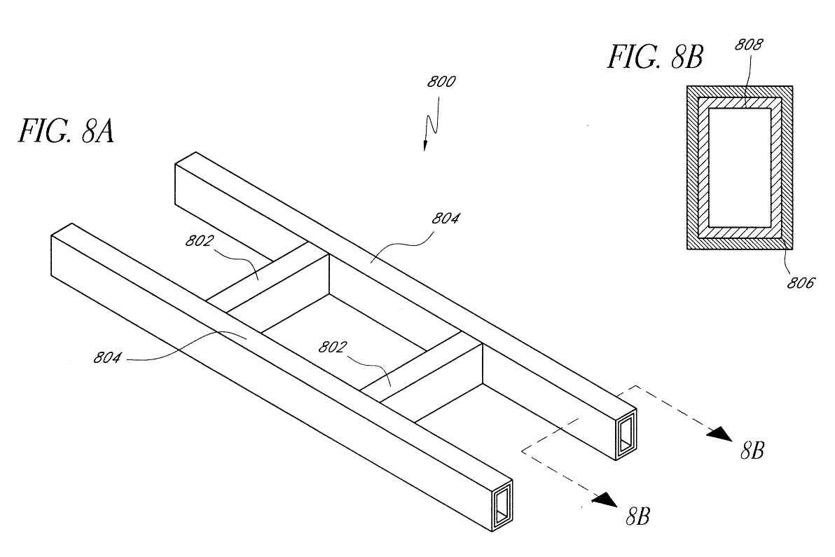

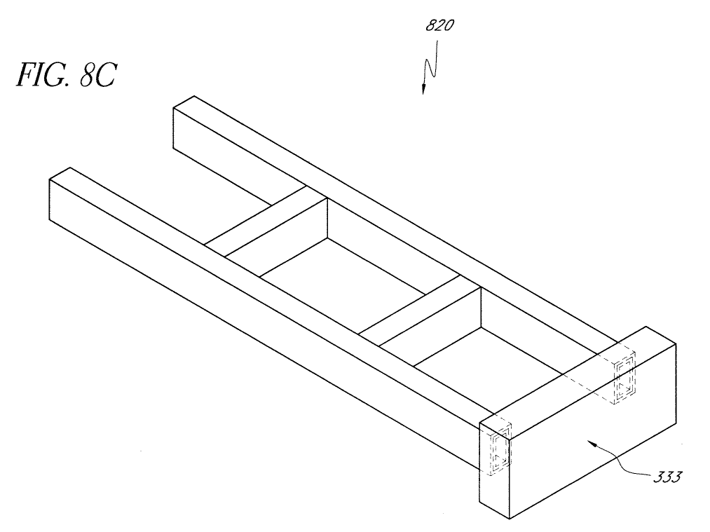

While one side of the photovoltaic cell 126 can be attached to the bottom conductive layer 120 by the die-attachment material 130, the top side of the photovoltaic cell 126 can connect with the top conductive layer 116 by at least one conductive interconnect, here two interconnects 122A, 122B as shown in FIG. 1. The interconnects 122A, 122B may comprise any material capable of conducting electricity from the photovoltaic cell 126 to the top conductive layer 116. For example, the interconnects 122A, 122B may comprise solder, metal filled epoxy, conductive welds, wire bonds, ribbon bonds, or foil connects. Therefore, when concentrated sunlight is received by the photovoltaic cell 126, the top conductive layer 116 and the bottom conductive layer 120 are configured to conduct current to and from the photovoltaic cell 126 to a conductive bus, for example, as illustrated in FIGS. 4 and 8A. Accordingly a receiver assembly is formed for receiving light and providing electricity generated by the PV cell 126. The receiver assembly also includes the base plate 140 having a first conductive layer 116 and second conductive layer 120, where the first conductive layer 116 and second conductive layer 120 are configured to provide a voltage differential when current is conducted in the first conductive layer 116 and the second conductive layer 120, for example, when exposed to light. When operable (e.g., generating electricity) the first conductive layer 116 and second conductive layer 120 are characterized by a voltage differential. The receiver assembly also includes a plurality of photovoltaic cells 126 mounted to the base plate 140, each cell 126 having a first terminal connected to the first conductive layer 116 and a second terminal connected to the second conductive layer 120.

In one embodiment, the top conductive layer 116 conducts the current generated by the photovoltaic cell 126 while the bottom conductive layer 120 serves as a ground. The current produced by the photovoltaic cell 126 may be conducted through the base plate 140 substantially without using wire conductors. For example, after electricity is conducted through interconnects 122A, 122B, and die attachment material 130, the electricity may be conducted through the base plate 140 without any wires. Additionally, the base plate 140 may be electrically connected to a plurality of other solar concentrating units (not shown) and distribute the current of the photovoltaic cell 126 shown as well as the current of the plurality of other solar cells similarly mounted in other portions of the base plate 140. In one embodiment, the voltage difference between the top conductive layer 116 and the bottom conductive layer 120 is approximately 3 volts and a relatively high current is produced by the embedded photovoltaic cells.

FIG. 2 depicts a cut-away view of an embodiment of a solar concentrating module 200 containing a group of solar concentrating units 100. The illustrated module includes 28 units 100 in a 4×7 array configuration, however, many other configurations are also possible. The module 200 includes a single primary lens assembly 102. The primary lens assembly 102 is supported by supporting structure 110. In this embodiment, the supporting structure 110 supports the edges of the primary lens assembly 102 and includes ribs that support the primary lens assembly 102 and define the individual solar concentrating units 100. The supporting structure 110 may include one or more lateral ventilation openings 202. The ventilation openings 202 may be configured to allow air to ventilate from unit to unit in module 200, as well as in and out of the module 200. The size of the openings 202 may be configured to regulate heat transfer within the module 200. FIG. 2 illustrates the base plate 140 including alignment features 114 to align the supporting structure 110. As discussed above, the alignment features 114 may include any structure capable of aligning the supporting structure on the top conductive layer 116 of the base plate 140. The dimensions of the module 200 may be chosen to optimize the power output of the solar concentrating units 100. For example, in one embodiment, PV cells of about 0.5 cm×0.5 cm (not shown) may be used in units that are included in a module with an area of about one square meter. In that example, the height of the supporting structure 110, measured from the base plate 140 to the primary lens assembly 102, may be about 300 mm.

Still referring to FIG. 2, each solar concentrating unit 100 includes a photovoltaic cell (as illustrated in FIG. 1) and the plurality of photovoltaic cells are electrically connected in parallel by base plate 140. This configuration produces power of a low voltage but at a high current. For example, the voltage differential across the top conductive layer and bottom conductive layer of base plate 140 may be about 3 volts or higher, for example between about 0.5 and about 48 volts direct current (DC). The current carried by the base plate 140 may later be converted to a higher voltage, for example, 120 volt alternating current (AC), 208 volt AC, or 480 volt 3 phase, using a step-up converter (not shown). A suitable step-up inverter and converter is available from OutBack Power Systems of Washington, USA. Producing power characterized by a low voltage generally enhances the safety of the concentrator module 200 by avoiding the high-voltage components and lines implemented in prior art systems.

Turning now to FIG. 3A, a perspective view of a group of solar concentrating modules 200A-200F is shown, according to one embodiment. Each of these modules 200A-200F comprises a plurality of units 100. The modules 200A-200F are connected mechanically (for support) and electrically to a frame structure 306. The frame structure 306 is configured to physically hold and support modules 200A-200F, and also to provide at least a portion of at least two conductive paths (or circuits), each conductive path capable of conducting electricity produced by the photovoltaic cells 126 in each unit. At least one of the conductive paths formed is a non-zero or non-ground conductive path. Frame 306 includes a supporting frame as well as at least two conductive members that can provide structural support for holding one or more modules. In the embodiment illustrated in FIG. 3A, the at least two conductive members are top conductive rail 304 and bottom conductive rail 310. The top conductive rail 304 and bottom conductive rail 306 provide two conductive paths capable of conducting electricity produced by the photovoltaic cells 126. The rails 304, 306 and can also provide structural support for solar concentrating modules 200A-200F. In other embodiments, the conductive members (e.g., the rails) can be disposed in locations on the frame other than the illustrated top and bottom of the frame, for example, on one or both sides of the frame structure, or both conductive members can be disposed alongside each other on the same side, top or bottom of the frame structure, or any combination thereof. In some embodiments the conductive members do not provide structural support themselves, but instead are attached to another member of the frame structure which provides structural support.

The frame 306 may be a box frame, an H-frame, a group of tubes coupled together, or any other structure capable of supporting at least one solar concentrating module 200. In this embodiment, the frame may be formed of any insulating material, for example, fiberglass, or the frame may include an outer insulting shell over a conductive material. In another embodiment illustrated in FIG. 8A, the supporting frame itself can be made from a conductive material in order to conduct electricity to an external load or power grid, for example. The top conductive rail 304 and the bottom conductive rail 310 may comprise any material capable of conducting electricity. For example, the top conductive rail 304 and the bottom conductive rail 310 may comprise aluminum or copper. The top conductive rail 304 and bottom conductive rail 310 can comprise a sheet of conductive material forming a relatively large cross-sectional conductor that minimizes electrical resistive losses when low voltage and high current electricity is conducted through the rails 304, 310.

The top conductive rail 304 can be mechanically and electrically connected with the top conductive layer 116 of a solar concentrating module 200 by means of a top connector ribbon 302. The bottom conductive rail 310 can be mechanically and electrically connected with the bottom conductive layer 120 by means of a bottom connector ribbon 308. The top connector ribbon 302 may be secured to the top conductive layer 116 by a conductive bolt, solder, metal filled epoxy, wire bond, foil connect, weld, or any other means such that the top connector ribbon 302 electrically connects the top conductive layer 116 and the top conductive rail 304. Similarly, the bottom connector ribbon 308 may be connected to the bottom conductive layer 120 by any means that electrically connects the connector ribbon 308 and the bottom conductive layer 320. The current produced by the solar concentrating modules 200A-200F may be conducted through the base plates 140 and frame 306 substantially without using wire conductors. For example, the base plates 140 and the conductive rails 304, 310 may be electrically connected by non-wire conductive hardware including conductive bolts, rivets, screws, or similar fasteners.

Still referring to FIG. 3A, the top conductive rail 304 and the bottom conductive rail 310 may run the length of the frame 306. In such configurations, the modules 200A-200F conduct electricity through the top and bottom conductive rails 304, 310 in a full parallel configuration. Alternatively, two or more of the modules 200A-200F may be electrically coupled in series by employing top and bottom conductive rails 304, 310 comprising a series of conductive portions (e.g, individual conductive segments) separated by insulators 312. The insulators 312 may comprise a nonconductive material, for example, a dielectric material, and prevent conduction of electricity from one top conductive rail portion to an adjacent top conductive rail portion. Strap conductors 314 may be used to detachably or releasably connect a top conductive rail portion adjacent a module 200 to a bottom conductive rail portion of an adjacent module 200, e.g., the cathode of at least one module with the anode of an adjacent module, thereby allowing two or more modules to be connected in series.

For example, an insulator 312 may exist between a top rail conductor portion adjacent module 200F and the top rail conductor portion adjacent module 200E Additionally, an insulator 312 (not shown) may exist between the bottom rail conductor portion (not shown) adjacent module 200F and the bottom rail conductor portion (not shown) adjacent module 200E. In this example, a strap conductor 314 may join the top conductive rail adjacent module 200F with the bottom conductive rail adjacent module 200E to connect modules 200F and 200E in series. In some embodiments, insulators 312 disposed on the top and bottom conductive rails are offset such that a strap connector 314 can more easily connect the modules in series. The strap conductor 314 may comprise any material capable of conducting electricity from one rail conductor portion to another. For example, a strap conductor 314 may comprise aluminum or copper. The strap conductors 314 may comprise a relatively large cross-sectional area that minimizes electrical resistive losses. By selectively mounting modules 200A-200F with conductive or insulated connections, the two-dimensional array of modules can be effectively wired together in the desired combination of parallel and series connections. For example, the use of top conductive rails 304, bottom conductive rails 310, insulators 312, and strap conductors 314 allows the modules 200 to be connected in full parallel, full series, series-parallel, and parallel series configurations, some of which are illustrated in FIGS. 9-12.

Turning now to FIG. 3B, a step-up voltage means, for example, an inverter or converter 333, may be electrically connected to the frame 306. Embodiments with an inverter can change the DC current to AC current. The inverter (if configured with a converter) or converter 333 may be configured to step-up the voltage conducted through the frame 306 to a higher voltage, for example, to 120 volt alternating current (AC), 208 volt AC, or to 480 volt 3 phase. Producing power characterized by a low voltage allows the base plates 140 and frame 306 to carry the electricity produced by the modules 200A—200 F while avoiding the use of high-voltage components and lines. As shown in FIG. 3B, an inverter or converted 333 may be electrically connected to the frame 306 in various positions. For example, the inverter or converter 333 may be electrically connected to the frame 306 at the end of the frame. The inverter or converter 333 may also be electrically and mechanically connected to the frame 306 on the side of the frame. The inverter or converter 333 may be electrically connected to the frame using conductive members 355, for example, a conductive bar or wire. The conductive members 355 may connect the inverter or converter 333 to various points on the frame including conductive rail portions or connector ribbons. The conductive members 355 may also electrically connected the inverter or converter 333 to the conductive layers of the base plate. The inverter or converter 333 may also be electrically connected to an external load (not shown).

FIG. 4 further illustrates the frame 306, described in FIG. 3A, with conductive rails configured to connect two or more solar concentrating modules (not shown) in series, according to one embodiment. The frame 306 includes nonconductive cross-members 316 and structure 318 that are configured to bear the weight of a plurality of solar concentrating modules attached thereto. The frame 306 may comprise an electrical non-conducting material, for example, fiberglass. The frame 306 may also comprise conductive material that is covered with an insulating shell, as described in reference to FIG. 8A. Attached to the nonconductive structure 318 are top conductive rail portions 304 and bottom conductive rail portions 310 which can run the length of the frame 306. As discussed above, the top conductive rail portions 304 and bottom conductive rail portion 310 may comprise any conductive material, for example, copper or aluminum. Insulators 312 may be used to separate top conductive rail portions 304 and bottom conductive rail portions. FIG. 4A shows a cross-section view of frame 306 with a top conductive rail 304 and bottom conductive rail 310 according to one embodiment. FIG. 4B further illustrates the strap conductors 314 that may connect the top conductive rail portion 304 of one module to the bottom conductive rail portion 310 of another module to connect a plurality of solar concentrating modules in series, in various configurations

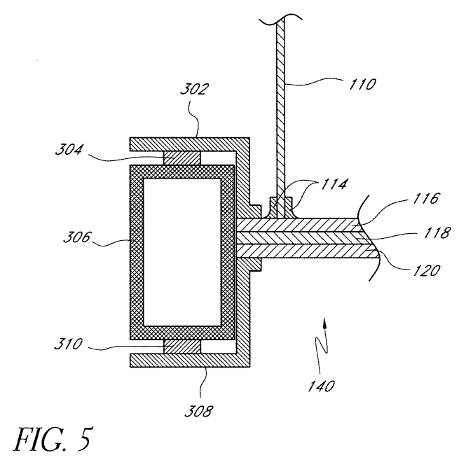

FIG. 5 is a cross-section view schematically illustrating the connections between the frame 306 and the base plate 140, according to one embodiment. As shown, the top conductive rail 304 is electrically coupled with the top conductive layer 116 with a connector ribbon 302 and the bottom conductive rail 310 is electrically coupled with the bottom conductive layer 120 with a connector ribbon 308. The connector ribbons 302, 308 may be joined with the conductive layers 116, 120 using a conductive bolt, solder, metal filled epoxy, wire bond, foil connect, weld, or any other means that allows electricity to conduct from the conductive layers 116, 120 to the conductive rails 304, 310. In addition to conducting electricity from the base plate 140 to the rails 304, 310, the ribbons 302, 308 may also rigidly affix the base plate 140 in place during assembly. As mentioned previously, base plate 140 and frame 306 may be electrically connected without wire conductors.

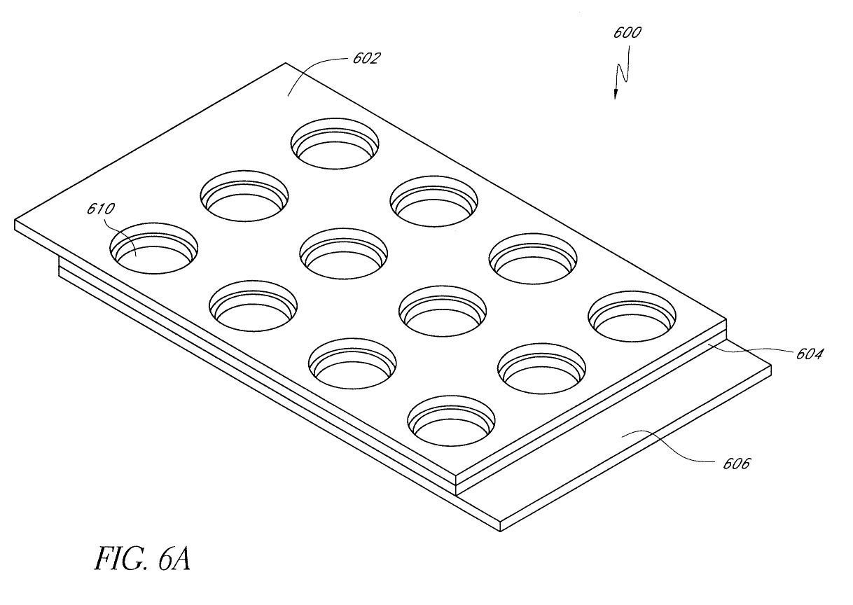

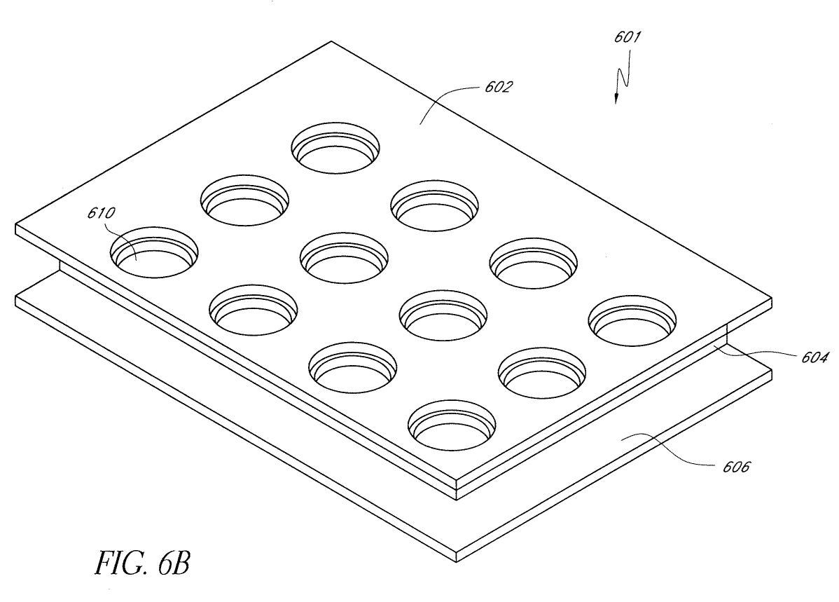

FIG. 6A illustrates a schematic view of an offset base plate 600, according to one embodiment. The offset base plate 600 includes a top conductor layer 602, a middle insulating layer 604, and a bottom conductive layer 606. The top conductive layer 602 and the bottom conductive layer 606 can be approximately the same size and the middle insulating layer 604 may be slightly smaller than the top conductive layer 602 and the bottom conductive layer 606. The top conductive layer 602 and the bottom conductive layer 606 may comprise any conductive material, for example, aluminum or copper. The middle insulating layer 604 may comprise and nonconductive material, for example, a dielectric material. FIG. 6A illustrates a first offset of the conductive layers, where the top conductive layer 602 is offset from the bottom conductive layer 606 such that the two layers do not align completely in the illustrated vertical direction. Offset base plate 601 also includes pockets 610. Pockets 610 comprise apertures or holes extending through the top conductive layer 602 and the middle insulating layer 604 that expose the bottom conductive layer 606. The pockets are configured to receive a photovoltaic cell (not shown) that may be attached to the bottom conductive layer 606 using some conductive connector, for example, die attachment material. Turning now to FIG. 6B, another embodiment of an offset base plate 601 is shown. FIG. 6B illustrates one example of a two-directional offset base plate 601. Base plate 601 includes a first offset, a top conductive layer 602 that is offset from a bottom conductive layer 606 in a first direction, and a second offset, a top conductive layer 602 that is offset from a bottom conductive layer 606 in a second direction. Offset base plate 601 also includes pockets 610 configured to receive a photovoltaic cell (not shown).

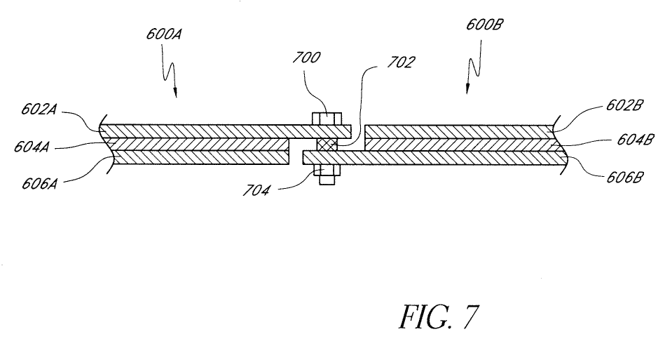

Turning now to FIG. 7, two offset base plates 600A, 600B are shown connected in series, according to one embodiment. The first offset base plate 600A includes a top conductive layer 602A that is offset from a bottom conductive layer 606A. The second offset base plate 600B includes a top conductive layer 602B that is offset from a bottom conductive layer 606B. The top conductive layer 602A of base plate 600A may be coupled with the bottom conductive layer 606B of base plate 600B by a conductive bolt 700 or similar conductive hardware. The conductive bolt 700 may be held in place by a locking feature 704, for example, a nut. A conductive spacer 702, for example, a conductive washer or star washer, may optionally be included to maintain a certain separation distance between top conductive layer 602A and bottom conductive layer 606B. In the illustrated embodiment, a conductive bolt 700 and locking feature 704 are used to couple offset base plate 600A to offset base plate 600B. However, any conductive structure or fastener capable of coupling one offset conductive layer of an offset base plate to another offset conductive layer of another offset base plate may be used. The use of offset base plates 600 allows solar concentrating modules (not shown) placed on offset base plates 600 to be connected in series by connecting the positive end of one photovoltaic cell to the negative end of another photovoltaic cell. Alternatively, the bolts, or hardware (e.g., screws, nails, rivets, etc.) 700 may comprise nonconductive material in order to structurally connect two or more base plates 600 without electrically connecting the base plates 600. Additionally, an offset base plate 601 (not shown) that is offset in two directions may be similarly coupled to other offset base plates 600 or 601 using conductive or nonconductive hardware. The use of offset base plates shown in FIGS. 6A, 6B, and 7 with a kit of conductive and nonconductive hardware is another way to wire solar concentrating modules together in a desired combination of parallel and series connection. Additionally, the conductive electrically connecting hardware, for example, bolt 700, may comprise a relatively large cross-sectional area that minimizes resistive losses

FIG. 8A depicts a frame 800 that may be used to support a group of solar concentrating modules (not shown) and also conduct electricity produced by the modules, according to one embodiment. The frame 800 may comprise a box frame, H-frame, or any other frame structure capable of supporting at least one solar concentrating module. The frame 800 includes at least two conductive members 804 that form at least two conductive paths and may include nonconductive cross members 802 configured to provide structural support for the frame. FIG. 8B shows a cross-section of frame 800 taken along line 8B-8B. As shown in FIG. 8B, the conductive members 804 of frame 800 may include an inner conductive layer 808 and an outer insulating layer or shell 806. The inner conductive layer 808 may comprise a relatively large cross-sectional area that minimizes resistive losses. Electricity may be carried by frame 800 along the at least two conductive members 804. In one example, a positive lead from a source of electricity (not shown), for example, a solar concentrating module, will be connected to one conductive member 804 of frame 800 and a negative lead from the source of electricity will be connected to another conductive member 804 of frame 800. When the conductive members 804 are surrounded by an outer insulating layer or shell 806, as shown in FIG. 8B, the leads from a power source may connect with the inner conductive layer using bolts (not shown), or similar hardware, placed through the insulating layer or shell 806, or similar conductive connectors. The conductive electrically connecting hardware may comprise a relatively large cross-sectional area that minimizes resistive losses. FIG. 8C illustrates a frame configuration 820 electrically connected to an inverter or converter 333. The inverter or converted 333 may be configured to step-up the voltage conducted through the frame to a higher voltage. By electrically connecting the frame to an inverter or converter, the frame and base plates (not shown) may carry electricity without the use of high-voltage components and lines. Inverter or converter 333 may be electrically connected with the conductive members 804 of the frame or inverter or converter 333 may be electrically connected to the conductive layers of one or more base plates (not shown).

FIGS. 9-12 illustrate several embodiments of electrical configurations for a plurality solar concentrating modules 904. The modules 904 may comprise the solar concentrating module depicted in FIG. 2 having base plates electrically connected in various parallel and series configurations using the conductive components and connections described above in reference to FIGS. 1-8. The electrical generation capability of each module 904, and the particular combination of parallel and/or series electrical connections of the modules 904, determine the voltage and current provided by each configuration. Such module configurations can be used to form individual tracking solar concentrators, which can be combined electrically to form a large group or field of solar concentrators. The configurations of modules 904 shown in FIGS. 9-12 may all be achieved by electrically connecting the conductive layers of the base plate 140 (e.g., shown in FIGS. 1, 6A, 6B, and 7) and the conductive members of frame structures (e.g., shown in FIGS. 3, 4, 8A, and 8) in various combinations.

Turning now to FIG. 9, a group of solar concentrating modules 904 is shown connected in a “full parallel” electrical configuration 900, according to one embodiment. The modules 904 are connected with electrical connections 906 that lead to a converter/inverter 902, which may be installed on the frame of the solar concentrator, proximal to the concentrator, or remotely from the concentrator. The component converter/inverter 902 can include either a voltage converter or a voltage inverter, or both. In a full parallel configuration, if each individual module produces current at 3 volts, the electricity provided to the converter/inverter 902 will also be at 3 volts. The electrical connections 906 may include any conductive materials capable of conducting electricity, for example, the frames shown in FIGS. 4A, 4B, 4C 8A, and 8B and the base plates shown in FIGS. 1, 6A, 6B, and 7. The electrical connections 906 may comprise connections with a relatively large cross-sectional area that minimizes resistive losses. In some embodiments the electrical connections only include relatively large cross-sectional area frames and base plates which form a conductive path to the converter/inverter 902 (or to an electrical connection point, e.g., a wire connection lead of the inverter/converter 902) without utilizing any wires in the conductive path. The converter/inverter 902 may optionally be used to step-up the electricity produced by the plurality of modules 904 to facilitate power transmission and distribution. For example, the converter/inverter 902 may be used to step up current at a relatively low voltage (e.g., 3 volts) carried by electrical connections 906 to a higher voltage, for example, 120 volt alternating current (AC), 208 volt AC, or 480 volt 3 phase. A suitable step-up inverter or converter 902 is available from OutBack Power Systems of Washington.

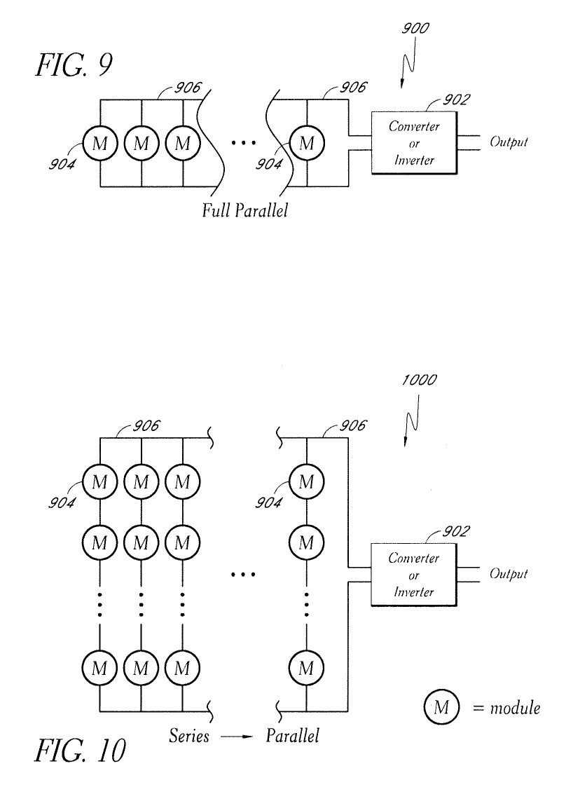

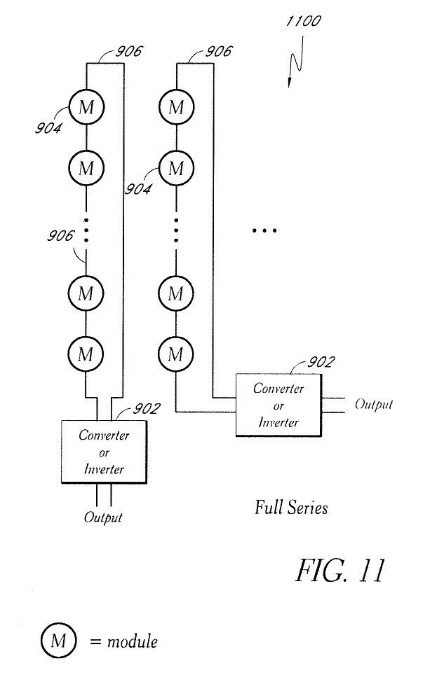

FIG. 10 depicts a group of electricity producing modules 904 connected in a “series-parallel” configuration 1000, according to one embodiment. The modules 904, electrical connections 906, and the converter/inverter 902, can be similar to those described in reference to FIG. 9. In FIG. 10, the modules 904 are connected such that between the electrical connections 906 the modules are electrically connected in a row in series, and the rows are electrically connected in parallel. In such a configuration, the voltage produced between the electrical connections 906, 908 will be the voltage produced by each row of modules, which will be the sum of the voltage produced by each module 904 in the a row. The voltage provided can be changed by adding, or removing, one or more modules 904 from each row. The current provided can be changed by adding (increasing current) or removing (decreasing current) one or more rows of modules 904.

FIG. 11 depicts two or more groups 1100 of electricity producing modules 904, each group connected in a “full series” configuration, according to another embodiment. The modules 904, electrical connections 906, and the converter/inverter 902, can be similar to those described in reference to FIG. 9. In FIG. 11, the voltage produced by the modules can be increased by adding additional one or more modules 904, or decreased by removing one or more modules 904. The electricity produced by of the group of modules 904 connected is provided to a converter/inverter 902. In some embodiments, the output of two or more converter/inverters 902 is combined such that the stepped up voltage from each group of modules is connected in parallel, providing increased current at the voltage output by the converter/inverter 902.

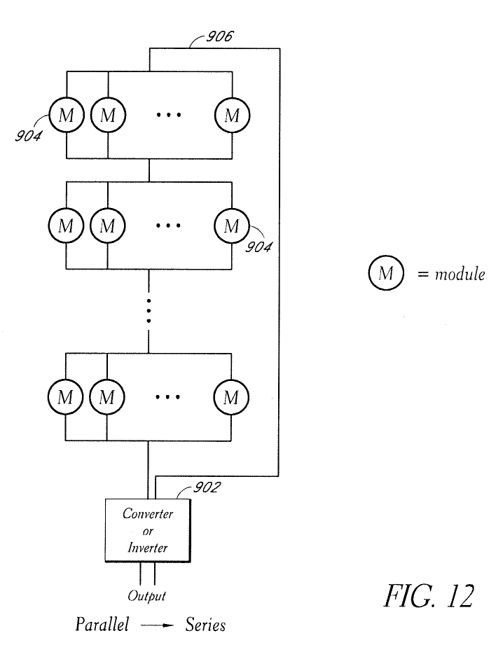

FIG. 12 depicts a group 1200 of electricity producing modules 904 connected in a “parallel-series” configuration, according to one embodiment. In this configuration, a group of two or more modules 904 are electrically connected in a parallel configuration, and each group is then electrically connected in series. A converter/inverter 902 is electrically connected to the two ends side of the series connections. In such a configuration, the voltage provided can be changed by adding (to increase voltage) or removing (to decrease voltage) one or more groups of modules connected in parallel. The current provided to the converter/inverter 902 by the module group 1200 can be increased by adding one or more modules in one or more of the groups of modules connected in parallel, or decreased by removing one or more modules in one or more of the groups of modules connected in parallel.

The foregoing description details certain embodiments of the invention. It will be appreciated, however, that no matter how detailed the foregoing appears in text, the invention can be practiced in many ways. As is also stated above, it should be noted that the use of particular terminology when describing certain features or aspects of the invention should not be taken to imply that the terminology is being re-defined herein to be restricted to including any specific characteristics of the features or aspects of the invention with which that terminology is associated. The scope of the invention should therefore be construed in accordance with the appended claims and any equivalents thereof.

What is claimed is:

1. A solar concentrator comprising:
at least one optical element for concentrating incident light;
a receiver assembly comprising
a base plate comprising a first conductive layer and second conductive layer, wherein the first conductive layer and second conductive layer are characterized by a voltage differential when exposed to light; and
a plurality of photovoltaic cells mounted to the base plate, each cell comprising a first terminal connected to the first conductive layer and a second terminal connected to the second conductive layer;
a frame for supporting the at least one optical element and receiver assembly;
step-up voltage means, electrically connected to the receiver assembly, for increasing said voltage differential;
an electrical circuit for conducting current generated by the receiver assembly, the circuit comprising
a first conductive member configured to conduct electricity between the first conductive layer and step-up voltage means; and
a second conductive member configured to conduct electricity between the second conductive layer and step-up voltage means.

2. The solar concentrator of claim 1, wherein the first conductive member is configured to conduct a current of non-zero voltage, and wherein the first conductive member consists essentially of a first portion of said frame.

3. The solar concentrator of claim 2, wherein the second conductive member is configured to provide a ground connection, and wherein the second conductive member consists essentially of a second portion of said frame different than the first portion.

4. The solar concentrator of claim 3, wherein
the first conductive layer is substantially planar and configured to connect directly to the first portion of said frame; and
the second conductive layer is substantially planar and configured to connect directly to the second portion of said frame,
wherein the first portion and second portion are electrically isolated from each other.

5. The solar concentrator of claim 4, wherein first conductive layer and second conductive layer are substantially parallel, and wherein the first conductive layer extends beyond the second conductive layer to form a first offset, and the second conductive layer extends beyond the first conductive layer to form a second offset.

6. The solar concentrator of claim 5, wherein the first conductive layer is configured to connect to the first portion of said frame at the first offset, and the second conductive layer is configured to connect to the second portion of said frame at the second offset.

7. The solar concentrator of claim 6, wherein the first offset of the first conductive layer of the base plate is further configured to connect to an offset of a second base plate, whereby the base plate is electrically connected in series or parallel with the second base plate.

8. The solar concentrator of claim 1, wherein
the first conductive member is configured to conduct a current of non-zero voltage; wherein a portion of the first conductive member consists essentially of a first rail mounted to said frame; and
the second conductive member consists essentially of a second rail mounted to said frame.

9. The tracking solar concentrator of claim 8, wherein
the first conductive layer is substantially planar and configured to connect directly to the first rail; and
the second conductive layer is substantially planar and configured to connect directly to the second rail,
wherein the first rail and second rail are electrically isolated from each other.

10. The tracking solar concentrator of claim 1, wherein the step-up voltage means is selected from the group consisting of: an inverter, a converter, or a combination thereof.

11. The tracking solar concentrator of claim 9, wherein said voltage differential provided to the step-up voltage means is in the range of between about 0.5 volts and about 48 volts.

12. The tracking solar concentrator of claim 10, wherein said voltage differential provided to the step-up voltage means is between 2 volts and 4 volts.

13. A solar concentrator device, comprising:
a base plate comprising
a planar first conductive layer;
a planar second conductive layer; and
a planar insulating layer disposed between the first and second conductive layers.

14. The device of claim 13, wherein at least one of the first conductive layer and the second conductive layer are less than about 5 mm thick.

15. The device of claim 13, wherein at least one of the first conductive layer and the second conductive layer are less than about 1 mm thick.

16. The device of claim 13, wherein at least one of the first conductive layer and the second conductive layer are less than about 0.5 mm thick.

17. The device of claim 13, further comprising:
a primary lens;
a secondary lens system disposed between the primary lens and the base plate; and
a support connected to the base plate and the primary lens for holding the primary lens above the secondary lens system.

18. The device of claim 17, further comprising a plurality of first alignment features disposed on the base plate, wherein at least one of the plurality of first alignment features is disposed between the support and the secondary lens system.

19. The device of claim 17, further comprising a photovoltaic cell, disposed below the secondary lens system to receive concentrated light propagating through the secondary lens system, wherein the photovoltaic cell is electrically connected to the first and second conductive layers.

20. The device of claim 18, further comprising a plurality of secondary alignment features disposed on the base plate for aligning the secondary lens system to the base plate, wherein the secondary lens system is connected to the base plate at the plurality of secondary alignment features.
